(19) United States
(12) Patent Application Publication
(10) Pub. No.: US 2014/0168036 A1
(43) Pub. Date: Jun. 19, 2014

(54) PIXEL CIRCUIT, ELECTRO-OPTIC DEVICE, AND ELECTRONIC APPARATUS

(71) Applicant: SEIKO EPSON CORPORATION, Tokyo (JP)

(72) Inventors: Takehiko KUBOTA, Matsumoto-shi (JP); Shin FUJITA, Suwa-shi (JP)

(73) Assignee: SEIKO EPSON CORPORATION, Tokyo (JP)

(21) Appl. No.: 14/179,024

(22) Filed: Feb. 12, 2014

Related U.S. Application Data
(62) Division of application No. 13/267,452, filed on Oct. 6, 2011.

(30) Foreign Application Priority Data
Oct. 21, 2010 (JP) 2010-236194

(51) Int. Cl. G09G 3/32

(52) U.S. Cl. CPC G09G 3/3258
USPC 345/80

(57) ABSTRACT

A pixel circuit includes a first light emitting device including a common electrode and a first opposed electrode connected to a first power supply line, and a second light emitting device including the common electrode and a second opposed electrode connected to the second power supply line. A first potential and a second potential are alternately supplied to a first power supply potential supplied to the first power supply line and a second power supply potential supplied to the second power supply line, and thus the first light emitting device and the second light emitting device alternately emit light.

The present application claims is a divisional application of U.S. patent application Ser. No. 13/267,452, filed Oct. 6, 2011, which claims priority from Japanese Patent Application No. 2010-236194, filed in the Japanese Patent Office on Oct. 21, 2010, the disclosure of each of which is hereby incorporated by reference in its entirety.

### BACKGROUND

1. Technical Field

The present invention relates to a pixel circuit provided with a light emitting device such as an organic EL (Electroluminescence) device, an electro-optic device including a display device or a lighting device having the pixel circuit, and an electronic apparatus provided with the electro-optic device.

2. Related Art

Recently, demand for 2-screen display devices displaying two different images on the left and right, or 3D displays performing 3D display by simultaneously outputting a left eye image and a right eye image, has increased along with the spread of car navigation systems having a 2-screen display function or 3D TVs.

There is demand for applying an organic EL device (hereinafter, referred to as “OLED device”) that is a light emitting device to a 2-screen display device to miniaturize the 2-screen display device and applying the device to an HMD (Head Mounted Display) or the like.

Generally, in the 2-screen display device, pixels for displaying a right image and pixels for display a left image are alternately arranged and the left and right images are optically separated by an optical device corresponding to the pixels such as a lenticular lens and a parallax barrier between the pixels and a viewer, to realize the display of different left and right images.

JP-A-2006-259192 is an example of the above-described related art.

In a 2-screen display device, in order to simultaneously display the left image and the right image, double the number of pixels is necessary as compared with a general 1-screen display device.

To realize the 2-screen displaying without decreasing the definition display as compared with a general 1-screen display device, it is necessary to arrange the pixels with double density, and a problem of increasing production cost or decreasing yields occurs due to complication of the production process.

### SUMMARY

An advantage of some aspects of the invention is to provide a high-precision 2-screen display device with a simple and easy configuration.

According to an aspect of the invention, there is provided a pixel circuit including: a common electrode; a first opposed electrode and a second opposed electrode that are opposed to the common electrode; and a light emission layer that is provided between the common electrode and the first and second opposed electrodes, wherein in a first light emission period, a first potential is supplied to the first opposed electrode to apply a voltage equal to or higher than a light emission threshold voltage of the light emission layer between the common electrode and the first opposed electrode, a current with a magnitude corresponding to a first image signal is supplied between the common electrode and the first opposed electrode, and a second potential is supplied to the second opposed electrode to apply a voltage lower than the light emission threshold voltage of the light emission layer between the common electrode and the second opposed electrode, and wherein in a second light emission period, the first potential is supplied to the second opposed electrode to apply a voltage equal to or higher than the light emission threshold voltage of the light emission layer between the common electrode and the second opposed electrode, a current with a magnitude corresponding to a second image signal is supplied between the common electrode and the second opposed electrode, and the second potential is supplied to the first opposed electrode to apply a voltage lower than the light emission threshold voltage of the light emission layer between the common electrode and the first opposed electrode.

According to the aspect of the invention, the first light emitting device and the second light emitting device are provided with the common electrode, and the first opposed electrode and the second opposed electrode, and thus it is possible to independently adjust the potential of the first opposed electrode and the potential of the second opposed electrode. For this reason, in the first light emission period, the potential of the first opposed electrode is set equal to or higher than the light emission threshold voltage of the first light emitting device, the potential of the second opposed electrode is set lower than the light emission threshold voltage of the second light emitting device, thus the first light emitting device emits light, and the second light emitting device does not emit light. On the other hand, in the second light emission period, the potential of the second opposed electrode is set equal to or higher than the light emission threshold voltage of the second light emitting device, the potential of the first opposed electrode is set lower than the light emission threshold voltage of the first light emitting device, thus the second light emitting device emits light, and the first light emitting device does not emit light.

Accordingly, two light emitting devices can emit light on the basis of the first image signal and the second image signal, respectively, and it is possible to apply the invention to a 2-screen display device or a 3D display device.

According to the aspect of the invention, since one pixel circuit is provided with two light emitting devices, it is possible to reduce the number of transistors of each light emitting device or the number of capacitance elements by half, as compared with the pixel circuit of the related art in which one pixel circuit is provided with one light emitting device. Therefore, according to the pixel circuit, it is possible to perform higher-precision display as compared with the display device of the related art in which one pixel circuit is provided with one light emitting device, and there is an advantage of a display device suitable for both a 2-screen display device and a 3D display device. In the pixel circuit described above, it is preferable that a current with a magnitude corresponding to a third image signal is supplied between the common electrode and the first and second opposed electrodes, the first potential is supplied to the first opposed electrode, and the first potential is supplied to the second opposed electrode, to cause the first light emitting device and the second light emitting device to simultaneously emit light.

According to the aspect of the invention, it is possible to cause two light emitting devices to emit light on the basis of the third image signal to display one image. According to the aspect of the invention, there is an advantage of being capable of easily switching between a mode of displaying one image on the basis of the third image signal and a mode of displaying two images on the basis of the first image signal and the second image signal by controlling the voltages applied to the first opposed electrode and the second opposed electrode.

According to another aspect of the invention, there is provided an electro-optic device including: a plurality of scanning lines; a plurality of data lines; a plurality of first power supply lines; a plurality of second power supply lines; a pixel circuit that is provided corresponding to intersections of the scanning lines and the data lines, and includes a common electrode, a first opposed electrode opposed to the common electrode and electrically connected to the first power supply line, a second opposed electrode opposed to the common electrode and electrically connected to the second power supply line, and a light emission layer provided between the first and second opposed electrodes and the common electrode, to supply a current corresponding to an image signal to the common electrode; a scanning line driving circuit that sequentially and exclusively outputs selection signals to the plurality of scanning lines; a data line driving circuit that supplies the image signals to the plurality of pixel circuits provided corresponding to the scanning lines selected by the selection signals through the plurality of data lines; and a potential control circuit that supplies at least any one of a first potential for applying a voltage equal to or higher than a light emission threshold voltage of the light emission layer between the first opposed electrode or the second opposed electrode and the common electrode, and a second potential for applying a voltage lower than the light emission threshold voltage of the light emission layer between the first opposed electrode or the second opposed electrode and the common electrode, to each of the plurality of first power supply lines and the plurality of second power supply lines, wherein in a first light emission period of causing the first light emitting device including the common electrode, the light emission layer, and the first opposed electrode to emit light, the potential control circuit supplies the first potential to the first opposed electrode of the plurality of pixel circuits provided corresponding to the scanning line selected by the selection signal through the first power supply line, and supplies the second potential to the second opposed electrode through the second power supply line, wherein in a second light emission period of causing the second light emitting device including the common electrode, the light emission layer, and the second opposed electrode to emit light, the potential control circuit supplies the first potential to the second opposed electrode of the plurality of pixel circuits provided corresponding to the scanning line selected by the selection signal through the second power supply line, and supplies the second potential to the first opposed electrode through the first power supply line.

According to the electro-optic device, two light emitting devices provided with the pixel circuits individually emit light, and it is possible to apply the electro-optic device to a 2-screen display device or a 3D display device.

According to the electro-optic device, since one pixel circuit is provided with two light emitting devices, it is possible to reduce the number of transistors of each light emitting device or the number of capacitance elements by half, as compared with the pixel circuit of the related art in which one pixel circuit is provided with one light emitting device. Therefore, according to the pixel circuit, it is possible to perform higher-precision display as compared with the display device of the related art in which one pixel circuit is provided with one light emitting device, and there is an advantage of a display device suitable for both a 2-screen display device and a 3D display device.

In the electro-optic device described above, it is preferable that the potential control circuit supplies the first potential to the first opposed electrode of the plurality of pixel circuits provided corresponding to the scanning line selected by the selection signal through the first power supply line, and supplies the first potential to the second opposed electrode through the second power supply line, to cause the first light emitting device and the second light emitting device to simultaneously emit light.

According to the electro-optic device, two light emitting devices in each pixel circuit simultaneously emit light to display one image. There is an advantage that it is possible to simply and easily switch between the 1-screen display and 2-screen display modes by the control of the data line driving circuit and the potential control circuit.

In the electro-optic device described above, it is preferable that the first light emission period has a length corresponding to one vertical scanning period, and sequentially starts for the plurality of scanning lines at the same time as start of outputting of the selection signal, the second light emission period has a length corresponding to one vertical scanning period, and sequentially starts for the plurality of scanning lines at the same time as end of the first light emission period, and the first light emission period and the second light emission period are alternately repeated.

According to the electro-optic device, the first light emission period and the second light emission period start before the selection signal falls to a low level after the selection signal becomes a high level. Accordingly, it is possible to prevent charges from unnecessarily moving in the pixel circuit according to the change of the potential of the first opposed electrode or the second opposed electrode. Accordingly, even after the selection signal becomes the low level, there is an advantage that the first image signal or the second image signal are accurately kept by the pixel circuit, and the pixel circuit accurately emits light with a brightness based on the first image signal or the second image signal.

In the electro-optic device described above, it is preferable that the first light emission period starts later than the start of the outputting of the selection signal by a first time, and ends earlier than the time after one vertical scanning period of the start of outputting of the selection signal by a second time, the second light emission period starts later than the start of the outputting of the selection signal by the first time, and ends earlier than the time after one vertical scanning period of the start of outputting of the selection signal by the second time, and the first time and the second time are times shorter than one horizontal scanning period.

According to the electro-optic device, since it is possible to provide a margin between the first light emission period and the second light emission period, there is an advantage that it is possible to prevent the first light emitting device E1 and the second light emitting device E2 from simultaneously emitting light.

In the electro-optic device described above, it is preferable that in the plurality of pixel circuits provided corresponding to the scanning lines, the first opposed electrode is commonly provided as one electrode, and the second opposed electrode is commonly provided as one electrode.

According to the electro-optic device, the first opposed electrode and the second opposed electrode are common, and thus there is an advantage that the production process is simplified and the yield is improved.

In the electro-optic device described above, it is preferable that when the plurality of pixel circuits provided corresponding to an arbitrary scanning line are a first pixel circuit group and the plurality of pixel circuits provided corresponding to a scanning line adjacent to the scanning line are a second pixel circuit group, the first opposed electrode included in the first pixel circuit group and the second opposed electrode included in the second pixel circuit group are commonly provided as one electrode.

According to the electro-optic device, the first opposed electrode and the second opposed electrode are commonly provided as one electrode, the short side of the common opposed electrode can be made about twice as long as the short side of the first electrode or the second electrode, and thus there is an advantage that the production is simplified and the yield is improved.

According to the electro-optic device, since the common opposed electrode has an area wider than that of the first opposed electrode and the second opposed electrode, it is possible to lower impedance of the common opposed electrode, and there is an advantage that it is possible to achieve low power consumption.

The electro-optic device described above may further include a parallax barrier formed of opening portions and light shield portions corresponding, one-to-one, to the plurality of pixel circuits, and the plurality of opening portions may lead light emitted from the first light emitting device, to a first area, and may lead light emitted from the second light emitting device, to a second area.

According to the electro-optic device, the position of the parallax barrier and the position and size of the opening portion are set such that the first area and the second area are positioned corresponding to the right eye and the left eye of the viewer, respectively, and thus the viewer can view different images with the right eye and the left eye, thereby realizing, for example, a 3D display device.

According to the electro-optic device, the position of the parallax barrier and the position and size of the opening portion are set such that the first area and the second area are matched with positions of two different viewers, respectively. Accordingly, it is possible to realize a 2-screen display device capable of displaying different images for two viewers positioned on both sides of the electro-optic device.

The electro-optic device described above, may further include lenticular lenses provided with a plurality of lenses corresponding, one-to-one, to the plurality of pixel circuits, the plurality of lenses may lead light emitted from the first light emitting device, to a first area, and may lead light emitted from the second light emitting device, to a second area.

According to the electro-optic device, the position and the size of the lenses are set such that the first area and the second area are positioned corresponding to the right eye and the left eye of the viewer, respectively, and thus the viewer can view different images with the right eye and the left eye, thereby realizing, for example, a 3D display device.

According to the electro-optic device, the position and the size of the lenses are set such that the first area and the second area are matched with positions of two different viewers, respectively. Accordingly, it is possible to realize a 2-screen display device capable of displaying different images for two viewers positioned on both sides of the electro-optic device.

According to still another aspect of the invention, there is provided an electronic apparatus including any of the electro-optic devices according to the aspects.

The electronic apparatus may be a 2-screen display device such as a car navigation device and an HMD, or a 1-screen display device such as a personal computer and a mobile phone.

According to the electronic apparatus, even when the 2-screen display device is performed, the display is performed not by different electro-optic devices, but one electro-optic device, and thus there is an advantage that it is possible to reduce the size and the weight of the device.

### BRIEF DESCRIPTION OF THE DRAWINGS

The invention will be described with reference to the accompanying drawings, wherein like numbers reference like elements.

FIG. 1 is a block diagram illustrating a display device according to an embodiment of the invention.

FIG. 2 is a circuit diagram illustrating a pixel circuit.

FIG. 3 is a timing chart illustrating an operation of the display device.

FIG. 4 is a timing chart illustrating an operation of the display device.

FIG. 5A to FIG. 5C are diagrams illustrating a state of the pixel circuit in each period.

FIG. 6 is a block diagram illustrating arrangement of cathodes of the display device.

FIG. 7A and FIG. 7B are cross-sectional views illustrating a structure of the display device.

FIG. 8A and FIG. 8B are diagrams light emission patterns of the display device.

FIG. 9A and FIG. 9B are cross-sectional views illustrating the display device when applying a parallax barrier or a lenticular lens to the display device.

FIG. 10 is a block diagram illustrating arrangement of cathodes of a display device according to a second embodiment of the invention.

FIG. 11 is a cross-sectional view illustrating a structure of the display device according to the second embodiment of the invention.

FIG. 12 is a timing chart illustrating an operation of the display device according to the second embodiment of the invention.

FIG. 13A and FIG. 13B are diagrams illustrating light emission patterns of the display device according to the second embodiment of the invention.

FIG. 14 is a circuit diagram illustrating a pixel circuit according to a modification 1 of the invention.

FIG. 15 is a block diagram illustrating arrangement of cathodes of a display device according to a modification 3 of the invention.

FIG. 16 is a perspective view illustrating an HMD (Head Mounted Display).

FIG. 17 is a perspective view illustrating an electronic apparatus (a personal computer).

FIG. 18 is a perspective view illustrating an electronic apparatus (a mobile phone).

### DESCRIPTION OF EXEMPLARY EMBODIMENTS

### A: First Embodiment

Hereinafter, various embodiments according to the invention will be described with reference to the accompanying drawings. In the drawings, the dimensions and ratios of sections are appropriately different from those of the real things.

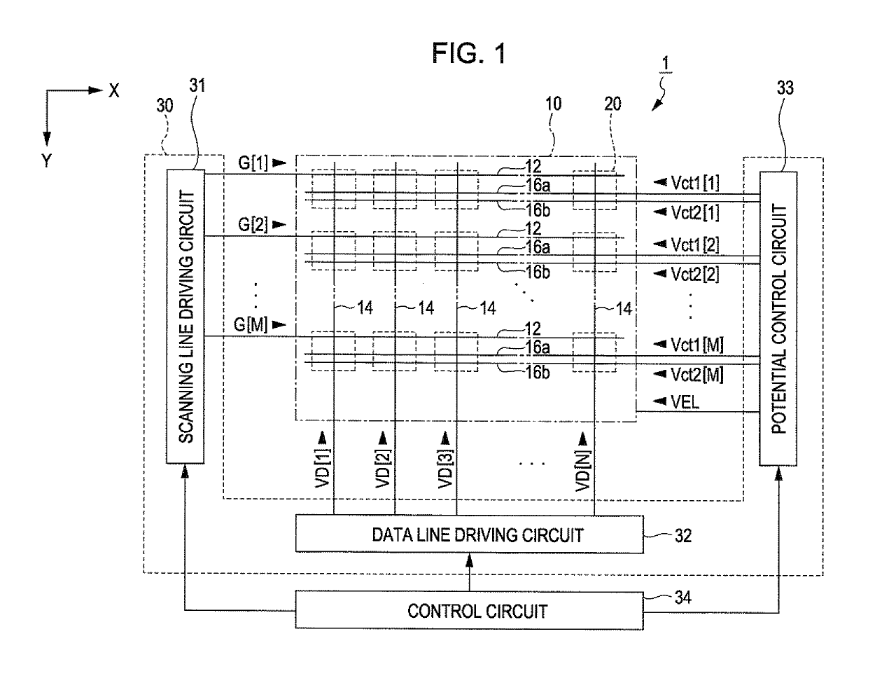

FIG. 1 is a block diagram illustrating a display device 1 according to a first embodiment of the invention.

The display device 1 includes a display area 10 in which a plurality of pixel circuits 20 are arranged, and a driving circuit 30 driving the pixel circuits 20. For example, the driving circuit 30 is dispersedly mounted on a plurality of integrated circuits. However, at least a part of the driving circuit 30 may be formed of a thin-film transistor formed on a substrate with the pixel circuits 20.

In the display area 10, M scanning lines 12 extending in the X direction, M first power supply lines 16a and M second power supply lines 16b extending in the X direction, and N data lines 14 extending in the Y direction intersecting with the X direction are formed (M and N are natural numbers equal to or more than 1). The M scanning lines 12 and the M first power supply lines 16a correspond, one-to-one, to each other, and the M scanning lines 12 and the M second power supply lines 16b correspond, one-to-one, to each other.

The plurality of pixel circuits 20 are arranged in a matrix of M rows×N columns corresponding to intersections of the scanning lines 12 and the data lines 14.

The driving circuit 30 includes a scanning line driving circuit 31, a data line driving circuit 32, a potential control circuit 33, and a control circuit 34.

The scanning line driving circuit 31 is a unit for sequentially selecting the plurality of pixel circuits 20 by a unit of row, and generates and outputs selection signals G [i] (i is an integer satisfying 1≦i≦M) for sequentially selecting the plurality of pixel circuits 20 by a unit of row to the scanning lines 12.

The data line driving circuit 32 outputs image signals VD [j] according gradations (hereinafter, referred to as “designated gradation”) in which the light emitting devices of the pixel circuits 20 have to emit light, to the j-th column data line 14, where j is an integer satisfying 1≦j≦N. The number of pixel circuits 20 of the j column is M from the first row to the M-th row. For this reason, in the following description, a signal supplied to the j-th column data line 14 is described as an image signal VD [j], and a signal supplied to the pixel circuit 20 of the i-th row and the j column is described as an image signal VD [i, j].

The potential control circuit 33 generates and outputs a first power supply potential Vct1 [i] (i is an integer satisfying 1≦i≦M) to the first power supply lines 16a, and generates and outputs a second power supply potential Vct2 [i] (i is an integer satisfying 1≦i≦M) to the second power supply lines 16b.

The control circuit 34 supplies various control signals such as clock signals and start pulses to the scanning line driving circuit 31, the data line driving circuit 32 and the potential control circuit 33, performs a process such as gamma correction on an input image signal (not shown) supplied from the outside, and supplies the signal to the data line driving circuit 32.

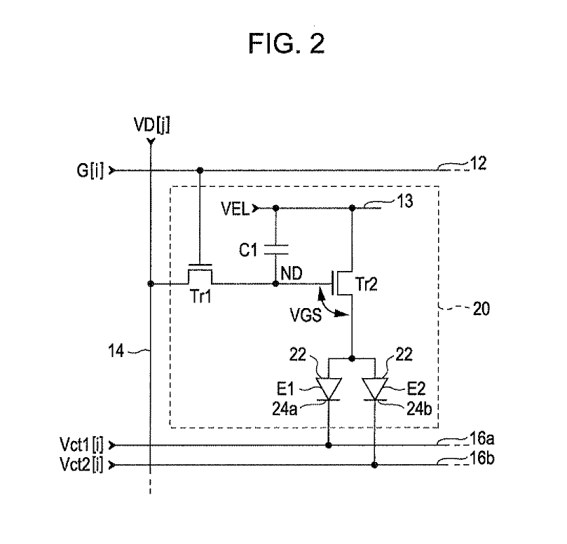

FIG. 2 is a circuit diagram illustrating the pixel circuit 20. In FIG. 2, the pixel circuit 20 positioned in the i row and the j column is representatively shown. The pixel circuit 20 includes a selection transistor Tr1, a driving transistor Tr2, a first light emitting device E1, a second light emitting device E2, and a capacitor C1.

The gate of the selection transistor Tr1 is connected to the i-th scanning line 12. One of the source and the drain of the selection transistor Tr1 is connected to the j-th column data line 14, and the other of the source and the drain of the selection transistor Tr1 is connected to a first node ND. In the first embodiment, the selection transistor Tr1 is formed of an n channel. When the selection signal G [i] supplied to the i-th row scanning line 12 becomes the high level, the selection transistor Tr1 is turned on, and the data line 14 and the first node ND are electrically connected to each other. In a period when the selection signal G [i] is the low level, the selection transistor Tr1 is turned off, the data line 14 and the first node ND are not electrically connected.

One electrode of the capacitor C1 is electrically connected to the first node ND, and the other electrode is electrically connected to the third power supply line 13. A third potential VEL is supplied to the third power supply line 13.

The driving transistor Tr2 is an example of a current supply unit, and supplies current to the first light emitting device E1 and the second light emitting device E2 to cause the light emitting devices to emit light.

The first light emitting device E1 and the second light emitting device E2 are an organic EL device provided with a light emitting layer formed of an organic EL (Electroluminescence) material between an anode and a cathode opposed to each other.

In the first light emitting device E1, the common electrode 22 is the anode (pixel electrode) and the first opposed electrode 24a is the cathode. In the second light emitting device E2, the common electrode 22 is the anode (pixel electrode) and the second opposed electrode 24b is the cathode. That is, the common electrode 22 serves as the common anode of the first light emitting device E1 and the second light emitting device E2.

In the first light emitting device E1 and the second light emitting device E2, when a voltage equal to or higher than the light emission threshold voltage Vth is applied between the anode and the cathode, a current flows from the anode to the cathode in the light emission layer. The light emission layer emits light with a brightness corresponding to the magnitude of the current.

In the first embodiment, the common electrode 22 is the anode, and the first opposed electrode 24a and the second opposed electrode 24b are the cathode. However, the invention is not limited to such a configuration, and the common electrode 22 may be the cathode, and the first opposed electrode 24a and the second opposed electrode 24b may be the anode.

The first opposed electrode 24a is electrically connected to the potential control circuit 33 through the first power supply line 16a. The second opposed electrode 24b is electrically connected to the potential control circuit 33 through the second power supply line 16b. The potential control circuit 33 applies any of the first potential VL and the second potential VH to the first opposed electrode 24a and the second opposed electrode 24b through the first power supply line 16a and the second power supply line 16b.

The potential control circuit 33 supplies the first power supply potential Vct1 [i] to the first opposed electrode 24a through the first power supply line 16a, and supplies the second power supply potential Vct2 [i] to the second opposed electrode 24b through the second power supply line 16b. Each of the first power supply potential Vct1 [i] and the second power supply potential Vct2 [i] becomes any potential of the first power supply potential VL and the second potential VH.

The first potential VL is a potential lower than the third potential VEL. The second potential VH is a potential higher than the first potential VL, and is a potential lower than the third potential VEL.

When the first potential VL is applied as the first power supply potential Vct1 [i], a voltage equal to higher than the light emission threshold voltage Vth is applied between the anode and the cathode of the first light emitting device E1, and the first light emitting device E1 can emit light. Meanwhile, when the second potential VH is applied as the first power supply potential Vct1 [i], a voltage lower than the light emission threshold voltage Vth is applied between the anode and the cathode of the first light emitting device E1, and the first light emitting device E1 cannot emit light.

When the first potential VL is applied as the second power supply potential Vct2 [i], a voltage equal to higher than the light emission threshold voltage Vth is applied between the anode and the cathode of the second light emitting device E2, and the second light emitting device E2 can emit light. Meanwhile, when the second potential VH is applied as the second power supply potential Vct2 [i], a voltage lower than the light emission threshold voltage Vth is applied between the anode and the cathode of the second light emitting device E2, and the second light emitting device E2 cannot emit light.

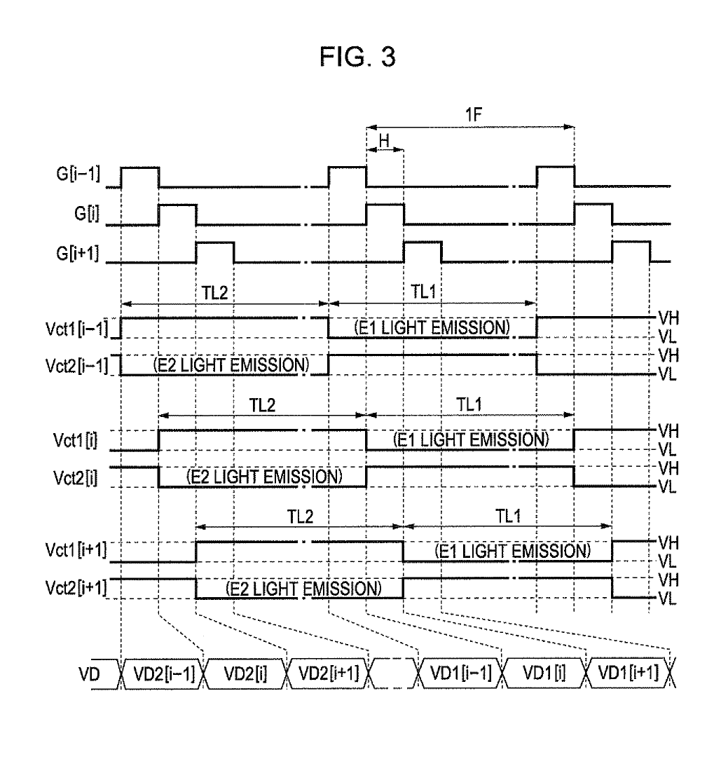

FIG. 3 is a timing chart illustrating an operation of the display device 1.

The selection signal G [i] is a pulse signal having a cycle corresponding to one vertical scanning period, and is supplied to the i-th row scanning line 12. The pulsewidth of the selection signal G [i], that is, a period in which the selection signal G [i] is the high level corresponds to one horizontal scanning period. The selection signal G [i] rises to the high level later than the selection signal G [i−1] by one horizontal scanning period. The M scanning lines 12 are sequentially and exclusively selected for each horizontal scanning period by the selection signals G [1] to G [M].

In the period in which the selection signal G [i] is the high level, that is, the period in which the scanning line 12 of the i-th row is selected, the image signals VD [i, 1] to VD [i, N] regulating the gradation of the pixel circuit 20 are supplied from the data line driving circuit 32 to the N pixel circuits 20 belonging to the i-th row.

The image signal VD [i, j] is formed of the first image signal VD1 [i, j] regulating the gradation of the first light emitting device E1 in the pixel circuits 20 and the second image signal VD2 [i, j] regulating the gradation of the second light emitting device E2 in the pixel circuits 20. In the period in which the selection signal G [i] is the high level, the first image signal VD1 [i, j] and the second image signal VD2 [i, j] are alternately supplied to the pixel circuits 20.

The first light emission period TL1 is a period corresponding to one vertical scanning period starting from the timing when the selection signal G [i] rises the high level, and sequentially starts for each scanning line 12. The second light emission period TL2 is a period corresponding to one vertical scanning period starting from the timing when the selection signal G [i] rises to the high level at the same time as the end of the first light emission period TL1, and sequentially starts for each scanning line 12. That is, the first light emission period TL1 and the second light emission period TL2 are a period regulated for each scanning line 12, and are alternately provided for each vertical scanning period.

The first power supply potential Vct1 [i] is set to the first potential VL in the first light emission period TL1, and is set to the second potential VH in the other period, that is, in the second light emission period TL2.

The second power supply potential Vct2 [i] is set to the first potential VL in the second light emission period TL2, and is set to the second potential VH in the other period, that is, in the first light emission period TL1.

As described above, the first light emitting device E1 and the second light emitting device E2 can emit light when the first potential VL is supplied to the cathode, and they cannot emit light when the second potential VH is supplied to the cathode. Accordingly, in each pixel circuit 20, the first light emitting device E1 can emit light on the basis of the first image signal VD1 [i, j] in the first light emission period TL1, the second light emitting device E2 can emit light on the basis of the second image signal VD1 [i, j] in the second light emission period TL2, and they are alternately repeated in the cycle of one vertical scanning period.

In FIG. 3, the first light emission period TL1 and the second light emission period TL2 start at the same time as when the selection signal G [i] rises to the high level, and end at the same time as when the selection signal G [i] falls to the low level. However, the invention is not limited to such a configuration.

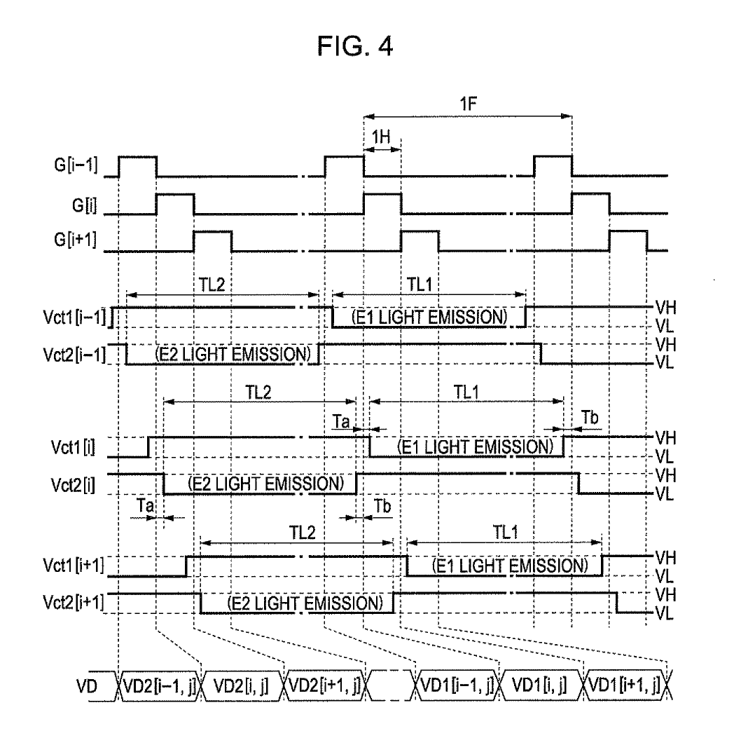

For example, as shown in FIG. 4, the first light emission period TL1 and the second light emission period TL2 may be set to start later than the timing when the selection signal G [i] rises to the high level by a period Ta and to start earlier than the timing when the selection signal G [i] falls to the low level by a period Tb. In this case, it is possible to provide a margin between the first light emission period TL1 and the second light emission period TL2, and thus it is possible to prevent the first light emitting device E1 and the second light emitting device E2 from simultaneously emitting light.

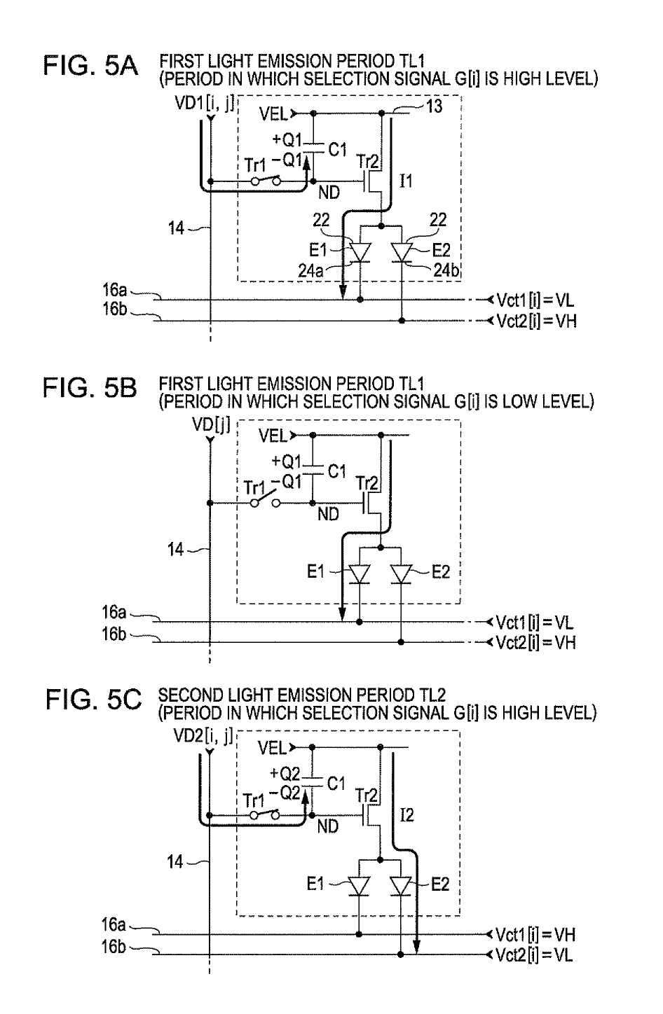

Operations of the pixel circuit 20 of the i-th row and the j-th column will be described with reference to FIG. 5A to FIG. 5C. FIG. 5A is a diagram illustrating an operation of the pixel circuit 20 in the period in which the selection signal G [i] is the high level, in the first light emission period TL1.

In the period shown in FIG. 5A, since the selection signal G [i] becomes the high level, the selection transistor Tr1 is turned on, and the data line 14 and the first node ND are electrically connected to each other. The first image signal VD1 [i, j] is supplied from the data line 14 to the gate of the driving transistor Tr2 and the capacitor C1 through the first node ND. Charges Q1 corresponding to the first image signal VD1 [i, j] are accumulated in the capacitor C1.

The first power supply potential Vct1 [i] is set to the first potential VL, and the voltage between both electrode of the first light emitting device E1 is higher than the light emission threshold voltage Vth. Accordingly, a current I1 with a magnitude based on the first image signal VD1 [i, j] applied to the gate of the driving transistor Tr2 flows in the first light emitting device E1, the first light emitting device E1 emits light with a brightness regulated by the first image signal VD1 [i, j]. Meanwhile, the second power supply potential Vct2 [i] is set to the second potential VH, and the voltage between both electrodes of the second light emitting device E2 is lower than the light emission threshold voltage Vth. Accordingly, the second light emitting device E2 does not emit light.

FIG. 5B is a diagram illustrating an operation of the pixel circuit 20 in the period in which the selection signal G [i] falls to the low level, in the period which is subsequent to the period shown in FIG. 5A, that is, in the first light emission period TL1.

In the period shown in FIG. 5B, since the selection signal G [i] is the low level, the selection transistor Tr1 is turned off, and the data line 14 and the first node ND are not electrically connected. However, the charges Q1 accumulated in the period shown in FIG. 5A are kept in the capacitor C1. Accordingly, the driving transistor Tr2 outputs the current I1 corresponding to the gate potential. The first power supply potential Vct1 [i] is set to the first potential VL, and the second power supply potential Vct2 [i] is set to the second potential VH. Accordingly, the first light emitting device E1 emits light with the brightness regulated by the first image signal VD1 [i, j] according to the current I1 with the magnitude based on the first image signal VD1 [i, j], but the second light emitting device E2 does not emit light.

FIG. 5C is a diagram illustrating an operation of the pixel circuit 20 in the period in which the selection signal G [i] is the high level, in the period which is subsequent to the period shown in FIG. 5B, that is, in the second light emission period TL2.

In the period shown in FIG. 5C, since the selection signal G [i] becomes the high level, the selection transistor Tr1 is turned on, and the second image signal VD2 [i, j] is supplied from the data line 14 to the gate of the driving transistor Tr2 and the capacitor C1 through the first node ND. Charges Q2 corresponding to the second image signal VD2 [i, j] are accumulated in the capacitor C1. The first power supply potential Vct1 [i] is set to the second potential VH, and the second power supply potential Vct2 [i] is set to the first potential VL. Accordingly, the second light emitting device E2 emits light with a brightness regulated by the second image signal VD2 [i, j] according to the current I2 with a magnitude based on the second image signal VD2 [i, j], but the first light emitting device E1 does not emit light.

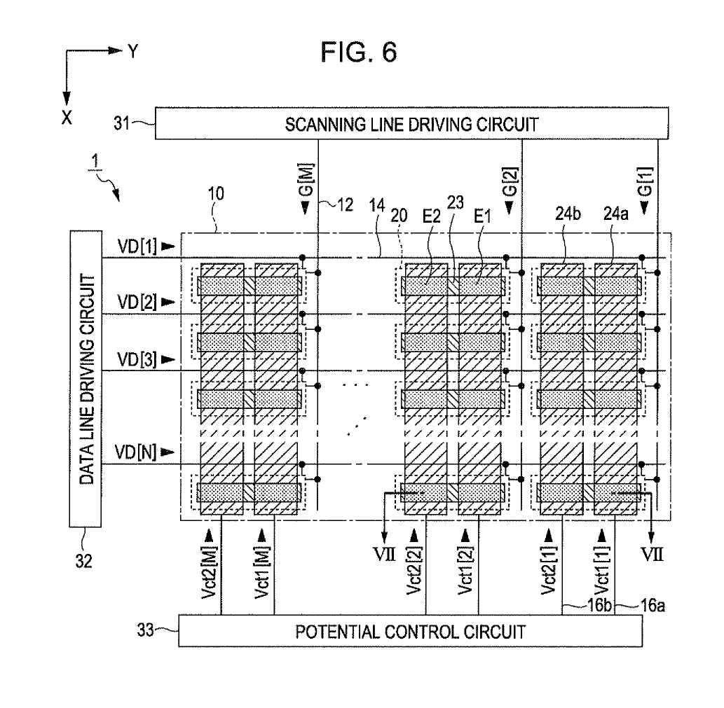

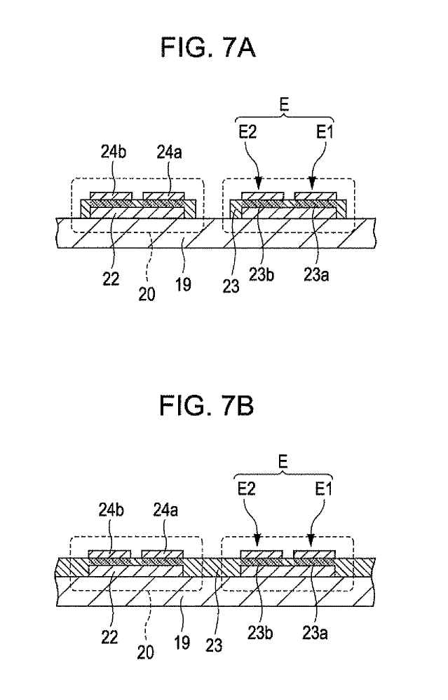

An example of disposition of the first opposed electrodes 24a and the second opposed electrodes 24b with respect to the common electrodes 22, the first light emitting devices E1, and the second light emitting devices E2 of the pixel circuits 20 will be described with reference to FIG. 6 to FIG. 7B. FIG. 6 is a block diagram illustrating disposition of the first opposed electrodes 24a and the second opposed electrodes 24b with respect to the pixel circuits 20.

As shown in FIG. 6, each pixel circuit 20 is provided with a light emission layer 23 having a rectangular shape formed of long sides parallel to the Y axis and short sides parallel to the X axis.

The first opposed electrode 24a has a rectangular shape formed of long sides parallel to the X axis and short sides parallel to the Y axis, and is commonly provided in the N first light emitting devices E1 provided in the N pixel circuits 20 connected to the scanning lines 12. The first opposed electrodes 24a are formed corresponding to the M scanning lines 12. Similarly to the first opposed electrode 24a, the second opposed electrode 24b having a rectangular shape formed of long sides parallel to the X axis and short sides parallel to the Y axis, and is commonly provided in the N second light emitting devices E2 provided in the N pixel circuits 20 connected to the scanning lines 12. The M second opposed electrodes 24b are formed corresponding to the M scanning lines 12. That is, one pair of the first opposed electrode 24a and the second opposed electrode 24b is disposed at a regular distance from each other to overlap with the light emission layer 23 of the N pixel circuit 20 connected to the scanning lines 12.

The M first opposed electrodes 24a are connected to the potential control circuit 33 by the M first power supply lines 16a, and the M second opposed electrodes 24b are connected to the potential control circuit 33 by the M second power supply lines 16b.

FIG. 7A is a cross-sectional view taken along the line VII-VII of the display area 10 shown in FIG. 6.

As shown in FIG. 7A, on the substrate 19, the common electrodes 22 are formed in a one-to-one correspondence with the pixel circuits 20, and the light emission layer 23 is formed on the substrate 19 and the common electrode 22. On the light emission layer 23, the first opposed electrode 24a and the second opposed electrode 24b are formed at a regular distance at the position corresponding to each common electrode 22. The first light emitting device E1 is formed of a first opposed electrode 23a positioned between the first opposed electrode 24a and the common electrode 22 in the light emission layer 23, the first opposed electrode 24a, and a part coming contact with the first light emitting portion 23a in the common electrode 22. Similarly, the second light emitting device E2 is formed of a second opposed electrode 23b positioned between the second opposed electrode 24b and the common electrode 22 in the light emission layer 23, the second opposed electrode 24b, and a part coming contact with the second light emitting portion 23b in the common electrode 22. That is, in the pixel circuit 20, the first light emitting device E1 and the second light emitting device E2 are arranged in a direction taken along the Y axis.

Although not shown, the scanning lines 12, the data lines 14, and the third power supply line 13 are formed on the substrate 19.

In FIG. 6 and FIG. 7A, the light emission layers 23 are formed in a one-to-one correspondence with the pixel circuits 20, but the invention is not limited to such a configuration.

That is, as shown in FIG. 7B, the light emission layer 23 may be commonly formed for the plurality of pixel circuits 20. In this case, it is not necessary to form the light emission 23 separately for each pixel circuit 20, and thus the production process can be simplified.

On the other hand, the light emission layer 23 may be formed separately between the first light emitting device E1 and the second light emitting device E2. In this case, a partition or the like is formed between the first light emitting device E1 and the second light emitting device E2. When the first light emitting device E1 and the second light emitting device E2 are separately formed, it is possible to reduce leakage of light between the light emission layers adjacent to each other, and it is possible to display a clearer image.

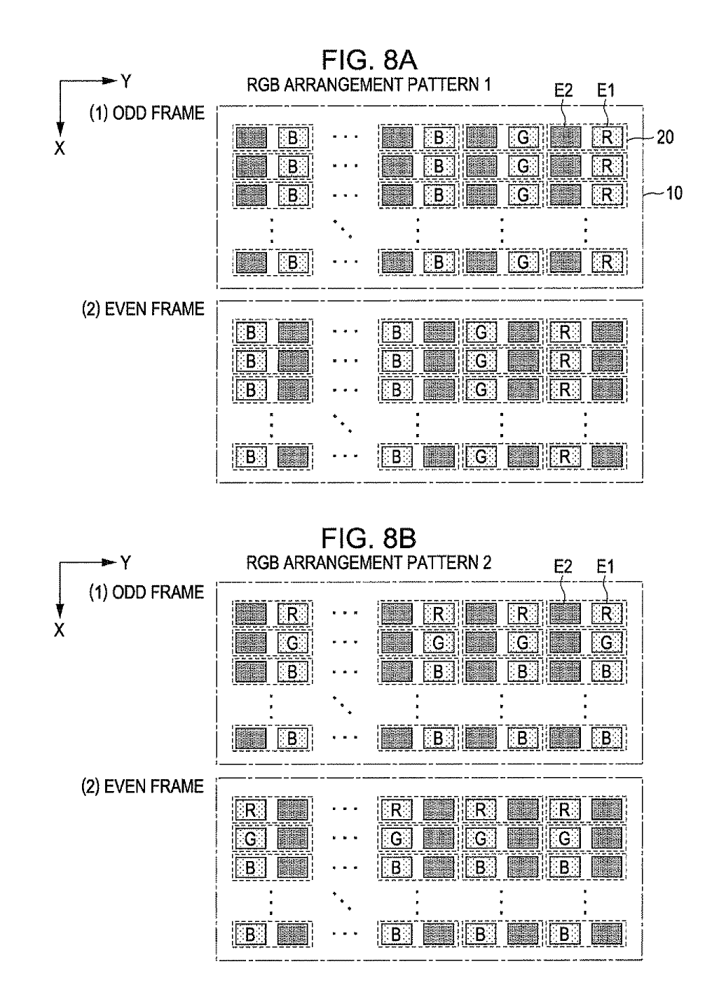

FIG. 8A and FIG. 8B are diagrams illustrating light emission patterns of the display area 10.

In the display area 10, the first light emitting device E1 of the pixel circuit 20 of each row sequentially emits light for one horizontal period on the basis of the first image signal VD1 [i, j] in an odd frame, and the second light emitting device E2 of the pixel circuit 20 of each line sequentially emits light for one horizontal period on the basis of the second image signal VD2 [i, j] in an even frame.

As shown in FIG. 8A, the N pixel circuits 20 emitting light with any one of the R, G, and B colors may be arranged in one row in a direction extending in the X-axis direction, and the column of the N pixel circuits 20 emitting light with R, G, and B colors may be arranged in a stripe shape in the Y-axis direction. In this case, the image signal VD [i] supplied from the data line driving circuit 32 is a signal representing only one color of the R, G, and B colors, and thus it is easy to generate the image signal VD [i].

As shown in FIG. 8B, the M pixel circuits 20 emitting light with any one of the R, G, and B colors may be arranged in one column in a direction extending in the Y-axis direction, and the row of the M pixel circuits 20 emitting light with the R, G, and B colors may be arranged in a stripe shape in the X-axis direction.

As described above, in the display device 1, the first light emitting device E1 displays the first image on the basis of the first image signal VD1 [i, j], and the second light emitting device E2 displays the second image on the basis of the second image signal VD2 [i, j]. Accordingly, the area where the first image can be viewed and the area where the second image can be viewed are separated using an optical method, and thus it is possible to realize a 2-screen display device capable of displaying different images on the left and right. In this case, the area where the first image can be viewed is set to be positioned for the right eye of the viewer, the area where the second image can be viewed is set to be positioned for the left eye, thus it is possible to view different images with both eyes, and possible to realize a 3D display device and the like.

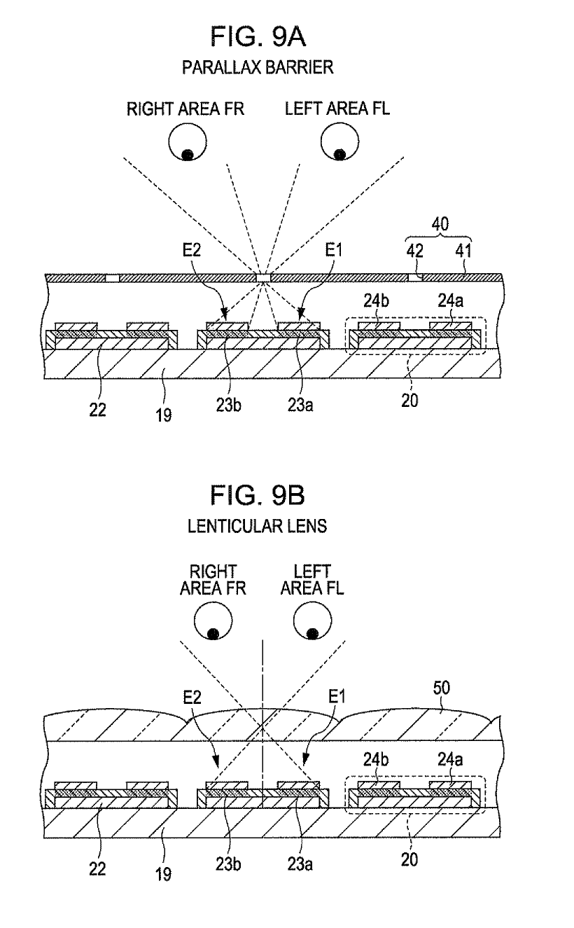

FIG. 9A and FIG. 9B show an example of the 2-screen display device separating the first image displayed by the first light emitting device E1 and the second image displayed by the second light emitting device E2.

FIG. 9A is a cross-sectional view illustrating the display device separating and displaying the first image displayed by the first light emitting device E1 and the second image displayed by the second light emitting device E2. A parallax barrier 40 is provided with a light shield portion 41 and an opening portion 42. The opening portion 42 is provided between the first light emitting device E1 and the second light emitting device E2, light directed to the left area FL of the light emitted by the first light emitting device E1 is absorbed by the light shield portion 41, and the light directed to the right area FR is output from the opening portion 42. Similarly, the light emitted by the second light emitting device E2 is output from the opening portion 42 only to the left area FL.

In this case, the position of the parallax barrier 40 and the position and the size of the opening portion 42 are set such that the right area FR and the left area FL are positioned for the right eye and the left eye of the viewer, respectively. Accordingly, to the viewer can view different images with the right eye and the left eye, and, for example, a 3D display device is realized.

The position of the parallax barrier 40 and the position and the size of the opening portion 42 are set such that the right area FR and the left area FL are matched with the positions of two different viewers, respectively. Accordingly, it is possible to realize a 2-screen display device capable of displaying different images for two viewers positioned on both sides of the display device 1.

Such a 2-screen display device may be also realized using a lenticular lens 50 instead of the parallax barrier 40. FIG. 93 is a diagram illustrating the cross-section of the display device separating the first and the second images.

In the lenticular lens 50, each lens constituting the lenticular lens 50 is provided between the first light emitting device E1 and the second light emitting device E2, the light emitted by the first light emitting device E1 is output to the right area FR, and the light emitted by the second light emitting device E2 is output to the left area FL. Accordingly, it is possible to realize a 2-screen display device displaying images in the right area FR and the left area FL.

In the description of the display device 1 according to the first embodiment, the first light emitting device E1 and the second light emitting device E2 exclusively emit light, and thus two different images are displayed. However, a first mode in which the display device 1 displays two different images and a second mode in which the first light emitting device E1 and the second light emitting device E2 simultaneously emit light to display one image may be switchable. In this case, the control circuit 34 changes the mode on the basis of a mode signal which designates a mode supplied from the outside. For example, in the first mode, the driving frequency is set to 120 Hz, and in the second mode, the driving frequency is set to 60 Hz.

In the second mode, waveforms of the first power supply potential Vct1 [i] and the second potential Vct2 [i] generated by the potential control circuit 33 are not alternately repeated between the first potential VL and the second potential VH as described above, but they are constantly set to the first potential VL. That is, it is preferable that the first light emitting device E1 and the second light emitting device E2 simultaneously emit light. That is, when the first light emitting device E1 and the second light emitting device E2 simultaneously emit light, the potential control circuit 33 supplies the first potential VL to the first opposed electrodes 24a of the pixel circuits 20 provided corresponding to the scanning line selected by the selection signal through the first power supply line 16a, and supplies the first potential VL to the second opposed electrodes 24b through the second power supply line 16b. In this case, the third image signal VD3 [i, j] regulating the gradation of the first light emitting device E1 and the second light emitting device E2 of the pixel circuits 20 is supplied to the N pixel circuits 20 provided corresponding to the i-th row scanning line 12 selected by the selection signal G [i].

As described above, it is possible to easily realize switching of the 2-dimensional display and the 3-dimensional display by merely switching the waveforms of the first power supply potential Vct1 [i] and the second power supply potential Vct2 [i] output from the potential control circuit 33.

In the first embodiment, one pixel circuit 20 is provided with two light emitting devices (the first light emitting device E1 and the second light emitting device E2). Accordingly, it is possible to reduce the number of transistors and capacitance elements of each light emitting device by half as compared with the pixel circuit of the related art in which one pixel circuit is provided with one light emitting device. Therefore, the display device 1 has an advantage that the high-precision display can be performed and it is a display device suitable for the 2-screen display device and the 3D display device, as compared with the display device of the related art in which one pixel circuit is provided with one light emitting device.

In the first embodiment, the first opposed electrodes 24a and the second opposed electrodes 24b are provided such that the long sides of the common electrodes 22 and the long sides of the first opposed electrodes 24a and the second opposed electrodes 24b are perpendicular to each other. Accordingly, it is possible to make the short sides of the first opposed electrodes 24a and the second opposed electrodes 24b long, as compared with the case where the first opposed electrodes 24a and the second opposed electrodes 24b are provided such that the short sides of the common electrodes 22 and the long sides of the first opposed electrodes 24a and the second opposed electrodes 24b are perpendicular to each other. Therefore, the display device 1 of the first embodiment has an advantage that the production is simplified and the yield is improved.

In the first embodiment, the first light emission period TL1 starts before the selection signal G [i] falls to the low level after the selection signal G [i] becomes the high level. Accordingly, there is an advantage that the first image signal VD1 [i, j] is accurately kept by the capacitor C1 even when the selection signal G [i] becomes the low level.

If the first light emission period TL1 starts after the selection signal G [i] falls to the low level, the first power supply potential Vct1 [i] applied to the first opposed electrode 24a drops from the second potential VH to the first potential VL after the selection signal G [i] falls to the low level. In this case, a part of the charges Q1 accumulated in the capacitor C1 move to a parasitic capacitor formed between the gate and the source of the driving transistor Tr2 at the timing when the potential of the first opposed electrode 24a drops from the second potential VH to the first potential VL, the potential of the first node ND also drops, and thus it is difficult that the capacitor C1 accurate keeps the first image signal VD1 [i, j]. Accordingly, in the first period TL1, the first light emitting device E1 emits light with a brightness different from the brightness regulated by the first image signal VD1 [i, j].

In the first embodiment, while the selection signal G [i] is the high level, the first power supply potential Vct1 [i] applied to the first opposed electrode 24a drops from the second potential VH to the first potential VL. Accordingly, the charges are prevented from moving from the capacitor C1 to the parasitic capacitor of the driving transistor Tr2, and thus there is an advantage that the first light emitting device E1 accurately emits light with the brightness regulated by the first image signal VD1 [i, j] in the first light emission period TL1. The second light emission period TL2 starts before the selection signal G [i] falls to the low level after the selection signal G [i] becomes the high level. Accordingly, there is an advantage that the second light emitting device E2 can accurately emit light with the brightness regulated by the second image signal VD2 [i, j].

### B: Second Embodiment

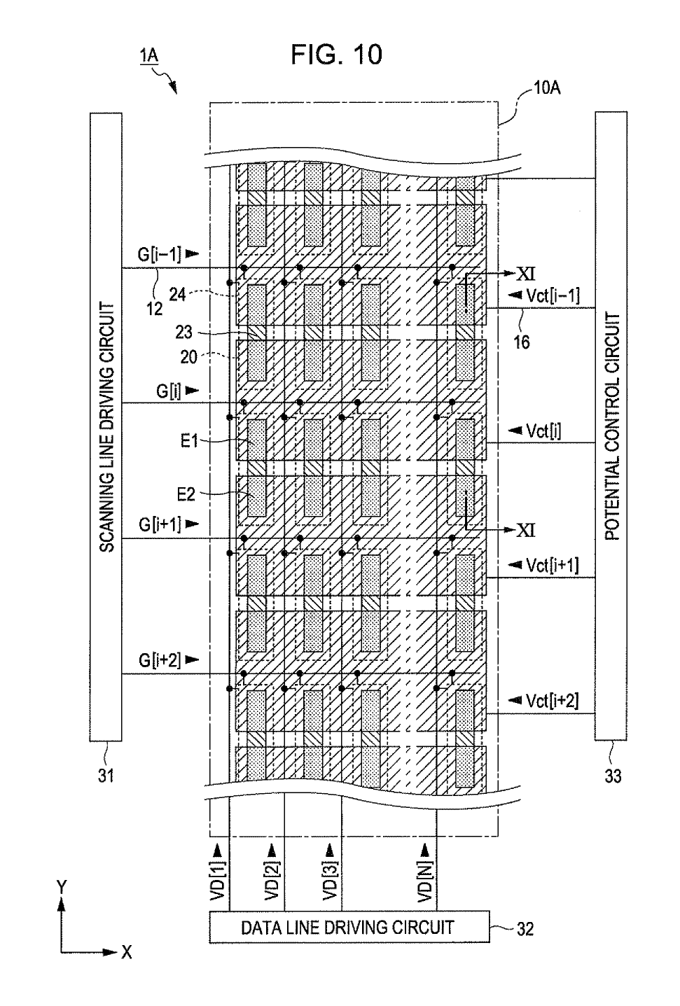

FIG. 10 is a block diagram illustrating disposition of pixel circuits 20 and opposed electrodes 24 according to a second embodiment. A display device 1A of the second embodiment has the same configuration as that of the display device 1 of the first embodiment, except that an opposed electrode 24 is provided instead of the first opposed electrode 24a and the second opposed electrode 24b, and a power supply line 16 is provided instead of the first power supply line 16a and the second power supply line 16b.

As shown in FIG. 10, each pixel circuit 20 of the display device 1A is provided with a light emission layer 23 having a rectangular shape formed of long sides parallel to the Y axis and short sides parallel to the X axis.

The opposed electrodes 24 have a rectangular shape formed of long sides parallel to the X axis and short sides parallel to the Y axis, and are provided to be common for N first light emitting devices E1 provided in N pixel circuits 20 connected to one scanning line 12 of two scanning lines adjacent to each other, and N second light emitting devices E2 provided in N pixel circuits 20 connected to the other scanning line 12 of two scanning lines 12 adjacent to each other. The opposed electrodes 24 are arranged in parallel at a regular distance from each other.

In the display device 1A, when N pixel circuits 20 provided corresponding to an arbitrary scanning line 12 are a first pixel circuit group and N of pixel circuits 20 provided corresponding to the scanning line adjacent to the scanning line are a second pixel circuit group, the first opposed electrode 24a of the first embodiment included in the first pixel circuit group and the second opposed electrode 24b of the first embodiment included in the second pixel circuit group are commonly provided as one electrode.

In the first line, the opposed electrodes 24 are provided only for N first light emitting devices E1 provided in N pixel circuits 20 connected to the first scanning line 12. In the M-th row, the opposed electrodes 24 are provided only for N second light emitting devices E2 provided in N pixel circuits 20 connected to the M-th row scanning line 12.

The M+1 opposed electrodes 24 are connected to the potential control circuit 33 by M+1 power supply lines 16. The power supply potential Vct [i] is supplied from the i-th power supply line 16 to the opposed electrode 24 of the i-th line.

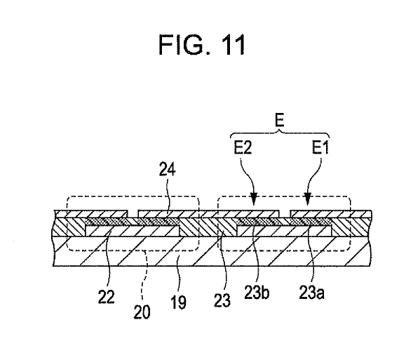

FIG. 11 is a cross-sectional view taken along the line XI-XI of the display area 10A shown in FIG. 10.

As shown in FIG. 11, on the substrate 19, the common electrodes 22 are formed in a one-to-one correspondence with the pixel circuits 20, and the light emission layer 23 is formed over one face of the substrate 19 and the common electrodes 22. The opposed electrodes 24 are formed on the light emission layer 23. As shown in FIG. 11, the opposed electrodes 24 are formed to cover a part of one common electrode 22 of two adjacent common electrodes 22 and a part of the other common electrode 22 of two adjacent common electrodes 22. The opposed electrodes are arranged at a regular distance from each other.

Two light emitting portions of the first light emitting portion 23a and the second light emitting portion 23b are formed on the common electrode 22 in the light emission layer 23 positioned between the opposed electrode 24 and the common electrode 22. The first light emitting device E1 is formed of the first light emitting portion 23a, and a part coming in contact with the first light emitting portion 23a in the opposed electrode 24 and the common electrode 22. The second light emitting device E2 is formed of the second light emitting portion 23b, and a part coming in contact with the second light emitting portion 23b in the opposed electrode 24 and the common electrode 22. Although not shown, the scanning lines 12, the data lines 14, and the third power supply line 13 are formed on the substrate 19.

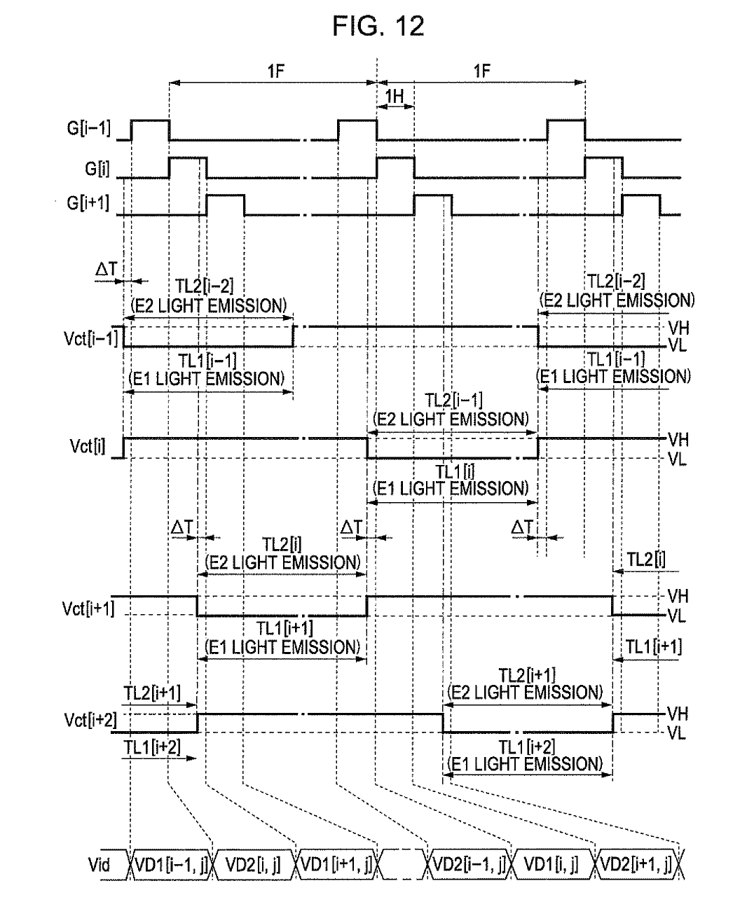

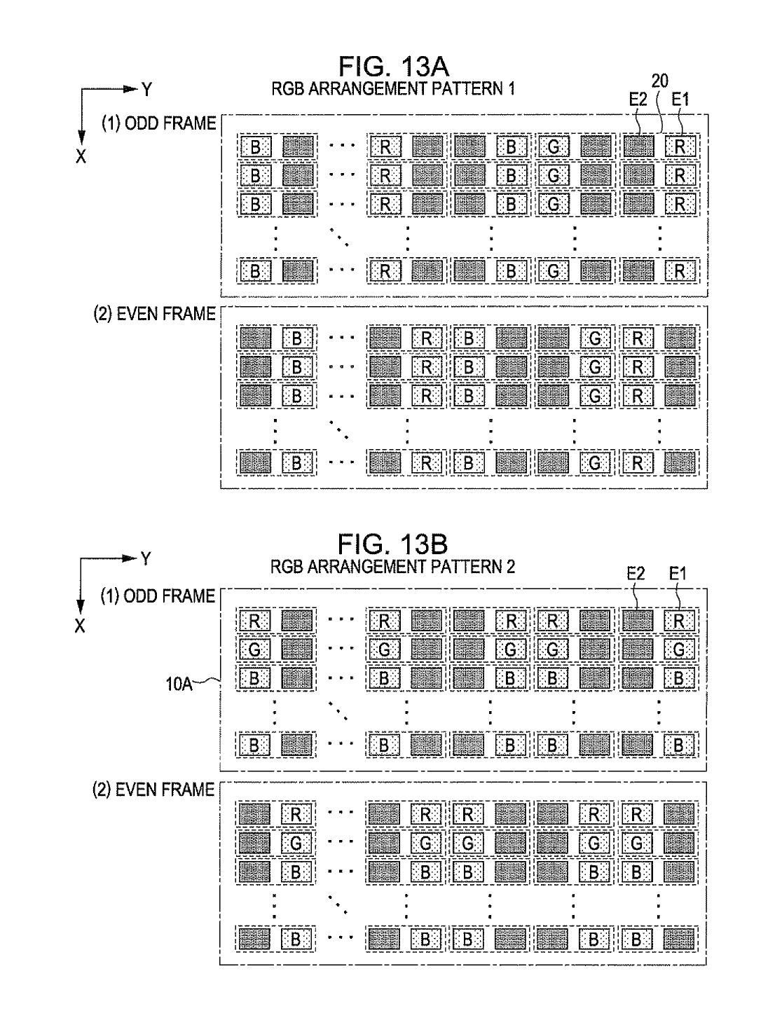

FIG. 12 is a timing chart illustrating an operation of the display device 1A according to the second embodiment.

In the pixel circuit 20 of the i-th row, the first light emission period TL1 [i] is a period in which the power supply potential Vct [i] supplied from the i-th row power supply line 16 is set to the first potential VL. In the first light emission period TL1 [i], the first light emitting device E1 emits light with the brightness regulated by the first image signal VD1 [i, j] supplied from the data line 14 in the period in which the selection signal G [i] is the high level.

In the pixel circuit 20 of the i-th row, the second light emission period TL2 [i] is a period in which the power supply potential Vct [i+1] supplied from the (i+1)-th row power supply line 16 is set to the first potential VL. In the second light emission period TL2 [i], the second light emitting device E2 emits light with the brightness regulated by the second image signal VD2 [i, j] supplied from the data line 14 in the period in which the selection signal G [i] is the high level.

In the pixel circuit 20 of the i row, the first light emission period TL1 [i] and the second light emission period TL2 [i] are set alternately for each vertical scanning period at the exclusive timing.

N first light emitting devices E1 provided in the pixel circuits 20 of the i row are connected to the opposed electrodes 24 common for N second light emitting devices E2 provided in the pixel circuit 20 of the (i−1) row adjacent to the i row, and thus the first light emission period TL1 [i] of the i row is the same period as the second light emission period TL2 [i−1].

The first light emission period TL1 [i] starts earlier by a period ΔT than the timing when the selection signal G [i] rises to the high level, and then ends earlier by the period ΔT than the timing when the selection signal G [i−1] rises to the high level. The second light emission period TL2 [i] starts earlier by the period ΔT than the timing when the selection signal G [i] falls to the low level, and then ends earlier by the period ΔT than the timing when the selection signal rises to the high level. Since the first light emission period TL1 [i] and the second light emission period TL2 [i] are set as described above, the first light emitting devices E1 of each row emit light with the brightness regulated by the first image signal VD1 [i, j], and the second light emitting devices E2 of each row emit light with the brightness regulated by the second image signal VD2 [i, j].

When the display device 1A perform the operation according to the timing chart shown in FIG. 12, the first light emitting devices E1 of the pixel circuits 20 of the i row emits light with the brightness regulated by the second image signal VD2 [i, j] different from the brightness regulated by the original first image signal VD1 [i, j], in the period ΔT before the selection signal G [i] rises to the high level. However, the period ΔT is shorter than one horizontal scanning period, and is short to the extent negligible as compared with the period in which the first light emitting device E1 emits light with the brightness regulated by the first image signal VD1 [i, j]. Accordingly, in actual, the first light emitting device E1 can emit light with the brightness regulated by the first image signal VD1 [i, j].

The period ΔT is also a period in which the second light emitting devices E2 of the pixel circuits 20 of the (i−1)-th row and the second image signal VD2 [i−1, j] is supplied from the data line 14.

As described above, for the second light emitting devices E2 of the pixel circuits 20 of the (i−1)-th row to accurately emit light with the brightness regulated by the second image signal VD2 [i−1, j], it is necessary to start the second light emission period TL2 [i−1] before the selection signal G [i−1] falls to the low level. Since the second light emitting devices E2 of the pixel circuit 20 of the (i−1)-th row are connected to the opposed electrodes 24 of the i-th line with the first light emitting devices E1 of the pixel circuits 20 of the i-th row, the second light emission period TL2 [i−1] becomes a period in which the power supply potential Vct [i] is set to the first potential VL. Accordingly, the power supply potential Vct [i] drops to the first potential VL at the timing (i.e., the timing earlier than by the period ΔT when the selection signal G [i] rises to the high level) earlier by the period ΔT than when the selection signal G [i−1] falls to the low level, and thus the second light emission period TL2 [i−1] and the first light emission period TL1 [i] simultaneously start.

FIG. 13A and FIG. 13B are diagrams illustrating light emission patterns of the display area 10A in the display device 1A of a third embodiment.

In the display area 10A, in an odd frame, the first light emitting devices E1 of the pixel circuits 20 positioned in an odd row (e.g., the i row) and the second light emitting devices E2 of the pixel circuits 20 positioned in an even row (e.g., the (i−1) line) alternately emit light sequentially for each horizontal period on the basis of the first image signal VD1 [i, j] and the second image signal VD2 [i−1, j], respectively. In an even frame, the second light emitting devices E2 of the pixel circuits 20 positioned in an odd row (e.g., the i row) and the first light emitting devices E1 of the pixel circuits 20 positioned in an even row (e.g., the (i−1) row) alternately emit light sequentially for each horizontal period on the basis of the second image signal VD2 [i, j] and the first image signal VD1 [i−1, j], respectively. That is, the display device 1A of the third embodiment displays an image based on both of the first image signal VD1 [i, j] and the second image signal VD2 [i−1, j] in both of the odd frame and the even frame.

As shown in FIG. 13A, the N pixel circuits 20 emitting light with any one of the R, G, and B colors may be arranged in one row in a direction extending in the X-axis direction, and the column of the N pixel circuits 20 emitting light with the R, G, and B colors may be arranged in a stripe shape in the Y-axis direction. In this case, the image signal VD [i] supplied from the data line driving circuit 32 is a signal representing one color of R color, G color, and B color, and thus it is easy to generate the image signal VD [i].

As shown in FIG. 13B, the M pixel circuits 20 emitting light with any one of the R, G, and B colors may be arranged in one column in a direction extending in the Y-axis direction, and the line of the M pixel circuits 20 emitting light with the R, G, and B colors may be arranged in a stripe shape in the X-axis direction.

In the second embodiment, the pixel circuit 20 of each line is not provided with two opposed electrodes of the first opposed electrode 24a and the second opposed electrode 24b as described in the first embodiment, but is provided with one opposed electrode 24. Accordingly, it is possible to make the short side of the opposed electrode 24 about twice as long as those of the first opposed electrode 24a and the second opposed electrode 24b of the first embodiment. Accordingly, the display device 1A of the second embodiment has an advantage that the production is simplified and the yield is improved.

Since the opposed electrode 24 has an area wider than those of the first opposed electrode 24a and the second opposed electrode 24b, it is possible to lower impedance. Accordingly, the display device 1A of the second embodiment has an advantage that it is possible to achieve low power consumption.

### C: Modified Example

The invention is not limited to the embodiments described above, and may be modified, for example, as follows.

### 1. Modified Example 1

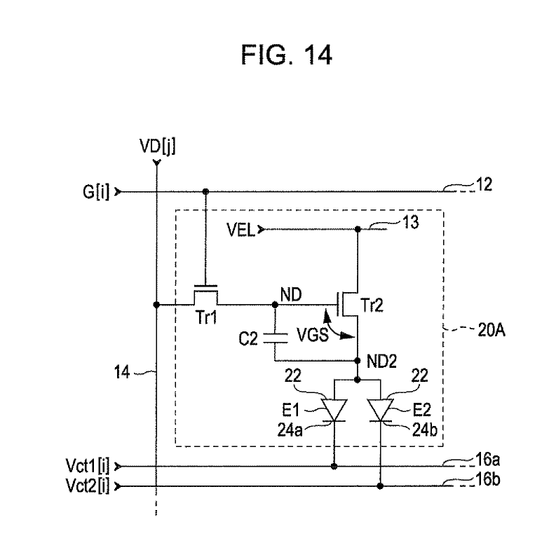

In the first embodiment and the second embodiment described above, each pixel circuit 20 is provided with the capacitor C1, one electrode of which is electrically connected to the first node ND, and the other electrode of which is electrically connected to the third power supply line 13. However, the invention is not limited to such a configuration, and a pixel circuit 20A shown in FIG. 14 may be used instead of the pixel circuit 20.

The pixel circuit 20A is provided with a capacitor C2, one electrode of which is electrically connected to the first node ND, and the other electrode of which is electrically connected to the second node ND2 positioned between the source of the driving transistor Tr2 and the common electrode 22. The pixel circuit 20A keeps the image signal VD [i, j] supplied from the data line 14, by the capacitor C2. Even after the selection signal G [i] becomes the low level, the first light emitting device E1 and the second light emitting device E2 emit light with the brightness based on the image signal VD [i, j] supplied from the capacitor C2.

Although not shown, the image signal VD [i, j] is not kept by the capacitance elements such as the capacitor C1 or the capacitor C2 like the pixel circuit 20, but the image signal VD [i, j] may be kept by a parasitic capacitor formed between the gate and the source of the driving transistor Tr2.

### 2. Modified Example 2

In the first embodiment described above, the first opposed electrode 24a is electrically connected to the potential control circuit 33 through the first power supply line 16a, and the second opposed electrode 24b is electrically connected to the potential control circuit 33 through the second power supply line 16b, but the invention is not limited to such a configuration. That is, a part or the entirety of the first power supply line 16a may be configured by the first opposed electrode 24a. In addition, a part or the entirety of the second power supply line 16b may be configured by the second opposed electrode 24b.

When the entirety of the first power supply line 16a is configured by the first opposed electrode 24a and the entirety of the second power supply line 16b is configured by the second opposed electrode 24b, it is preferable that the first opposed electrode 24a and the second opposed electrode 24b extend to the potential control circuit 33, a connection portion such as a though-hole is configured at the end thereof, to be electrically connected to the transistor of the output stage of the potential control circuit 33. In this case, it is not necessary to form total 2M first power supply lines 16a and second power supply lines 16b in the display area 10, and thus there is an advantage that the production process is simple and the yield is improved.

Similarly, in the second embodiment, the opposed electrode 24 is electrically connected to the potential control circuit 33 through the power supply line 16, but the invention is not limited to such a configuration. That is, a part or the entirety of the power supply line 16 may be configured by the opposed electrode 24 in the same manner as the modified example described above. When the entirety of the power supply line 16 is configured by the opposed electrode 24, the opposed electrode 24 is directly connected to the potential control circuit 33. Also in this case, it is not necessary to form M+1 power supply lines 16 in the display area 10A, and thus there is an advantage that the production process is simple and the yield is improved.

### 3. Modified Example 3

In the first embodiment, the second embodiment, and the third embodiment, the first light emitting device E1 and the second light emitting device E2 are arranged in a line in the direction along the Y axis with respect to each pixel circuit 20, but the invention is not limited to such a configuration.

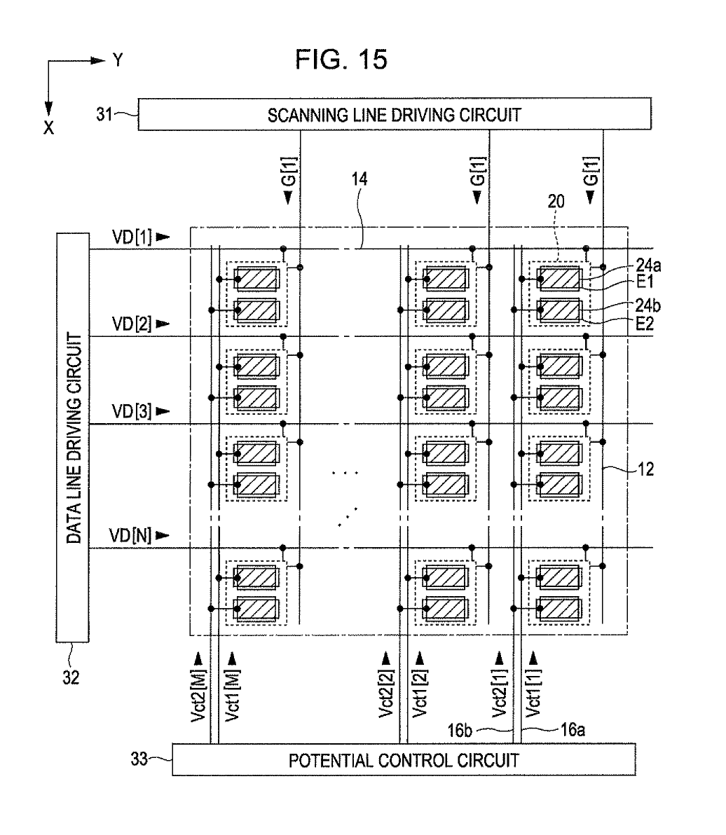

That is, as shown in FIG. 15, in each pixel circuit 20, the first light emitting device E1 and the second light emitting device E2 may be arranged in a line in the direction along the X axis.

In this case, the first opposed electrode 24a and the second opposed electrode 24b are individually formed in each pixel circuit 20. M first power supply lines 16a are provided corresponding to M scanning lines 12, to be connected to N first opposed electrodes 24a provided in N pixel circuits 20 connected to the same scanning line 12. Similarly, M second power supply lines 16b are provided corresponding to M scanning lines 12, to be connected to N second opposed electrodes 24b provided in N pixel circuits 20 connected to the same scanning line 12.

### D: Applications

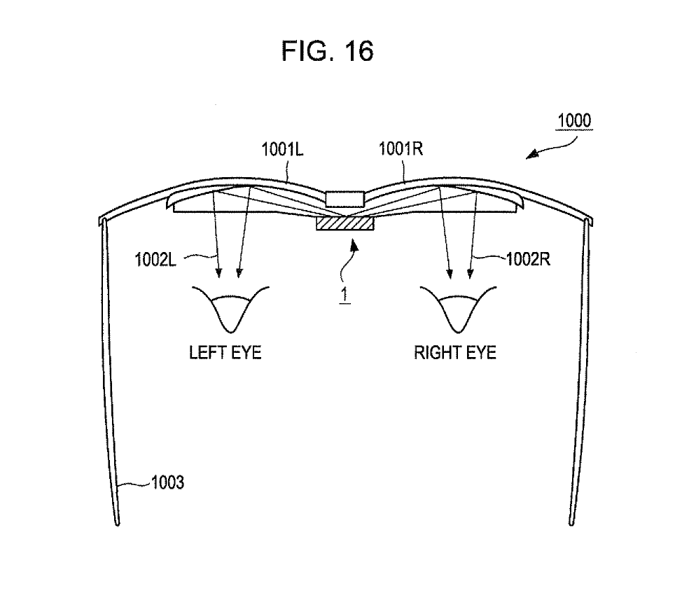

Next, an electronic apparatus using the display device 1 according to the aspects described above will be described. FIG. 16 to FIG. 18 show examples of the electronic apparatus employing the display device 1 as the display device.

FIG. 16 is a cross-sectional view illustrating a configuration of an HMD (Head Mounted Display) 1000 employing the display device 1. The HMD 1000 includes the display device 1 displaying a first image 1002L and a second image 1002R, a light guide plate 1001L guiding the first image 1002L to the left eye of the viewer, a light guide plate 1001R guiding the second image 1002R to the right eye of the viewer, and a frame 1003. The HMD 1000 may be utilized as the 3D display device.

Since the HMD 1000 employs the display device 1, the first image 1002L and the second image 1002R are not displayed by display devices different from each other, but are displayed by one display device 1. Accordingly, there is an advantage that it is possible to reduce the size and the weight of the apparatus.

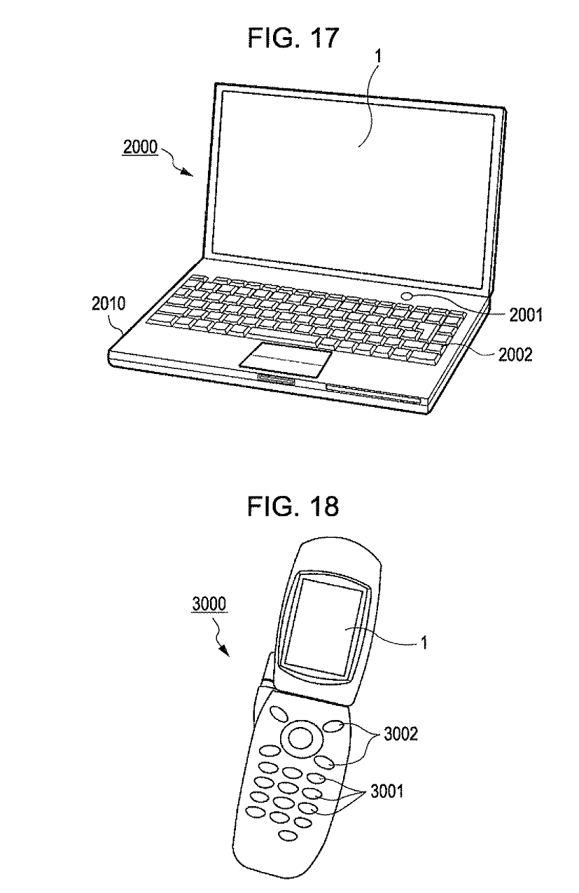

FIG. 17 is a perspective view illustrating a configuration of a mobile personal computer employing the display device 1. The personal computer 2000 includes the display device 1 displaying various images, and a main body unit 2010 provided with a power switch 2001 and a keyboard 2002.

FIG. 18 is a perspective view illustrating a configuration of a mobile phone employing the display device 1. The mobile phone 3000 includes a plurality of operation buttons 3001 and scroll buttons 3002, and the display device 1 displaying various images. The screen displayed on the display device 1 is scrolled by operating the scroll buttons 3002.

The electronic apparatus applying the display device 1 according to the invention may be a car navigation device, a digital still camera, a television, a video camera, a pager, an electronic scheduler, an electronic paper, a calculator, a word processor, a workstation, a video phone, a POS terminal, a printer, a scanner, a copier, a video player, an apparatus provided with a touch panel, and the like, in addition to the apparatuses shown as examples in FIG. 16 to FIG. 18.

What is claimed is:

1. An electro-optic device comprising:
a plurality of scanning lines;
a plurality of data lines;
a plurality of first power supply lines;
a plurality of second power supply lines;
a plurality of pixel circuits that are provided corresponding to intersections of the scanning lines and the data lines, each of the plurality of pixels including:
a common electrode,
a first opposed electrode opposed to the common electrode and electrically connected to a respective one of the plurality of first power supply lines,
a second opposed electrode opposed to the common electrode and electrically connected to a respective one of the plurality of the second power supply lines, and
a light emission layer provided between the first opposed electrode and the common electrode and between the second opposed electrode and the common electrode, to supply a current corresponding to an image signal to the common electrode;
a scanning line driving circuit configured to sequentially and exclusively output selection signals to the plurality of scanning lines;
a data line driving circuit configured to supply the image signals to the plurality of pixel circuits provided corresponding to the scanning lines selected by the selection signals through the plurality of data lines; and
a potential control circuit configured to supply at least any one of (1) a first potential for applying a voltage equal to or higher than a light emission threshold voltage of the light emission layer between the first opposed electrode or the second opposed electrode and the common electrode, and (2) a second potential for applying a voltage lower than the light emission threshold voltage of the light emission layer between the first opposed electrode or the second opposed electrode and the common electrode, to each of the plurality of first power supply lines and the plurality of second power supply lines,
wherein in a first light emission period of causing a first light emitting device to emit light, the potential control circuit supplies the first potential to the first opposed electrodes of the plurality of pixel circuits provided corresponding to the scanning line selected by the selection signal through the first power supply line, and supplies the second potential to the second opposed electrode through the second power supply line, the first light emitting device including the common electrode, the light emission layer, and the first opposed electrode,
wherein in a second light emission period of causing a second light emitting device to emit light, the potential control circuit supplies the first potential to the second opposed electrodes of the plurality of pixel circuits provided corresponding to the scanning line selected by the selection signal through the second power supply line, and supplies the second potential to the first opposed electrode through the first power supply line, the second light emitting device including the common electrode, the light emission layer, and the second opposed electrode,
wherein when a first plurality of the plurality of pixel circuits provided corresponding to an arbitrary scanning line are a first pixel circuit group and a second plurality of the plurality of pixel circuits provided corresponding to a scanning line adjacent to the arbitrary scanning line are a second pixel circuit group, the first opposed electrode included in the first pixel circuit group and the second opposed electrode included in the second pixel circuit group are commonly provided as one electrode.

2. The pixel circuit according to claim 1, wherein
a current with a magnitude corresponding to a third image signal is supplied between the common electrode and the first and second opposed electrodes,
the first potential is supplied to the first opposed electrode, and
the first potential is supplied to the second opposed electrode, to cause the first light emitting device and the second light emitting device to simultaneously emit light.

3. The electro-optic device according to claim 1, wherein the potential control circuit supplies the first potential to the first opposed electrodes of the plurality of pixel circuits provided corresponding to the scanning line selected by the selection signal through the first power supply line, and supplies the first potential to the second opposed electrodes through the second power supply line, to cause the first light emitting device and the second light emitting device to simultaneously emit light.

4. The electro-optic device according to claim 1, wherein the first light emission period has a length corresponding to one vertical scanning period, and sequentially starts for the plurality of scanning lines at the same time as start of outputting of the selection signal,
wherein the second light emission period has a length corresponding to one vertical scanning period, and sequentially starts for the plurality of scanning lines at the same time as end of the first light emission period, and
wherein the first light emission period and the second light emission period are alternately repeated.

5. The electro-optic device according to claim 1, wherein the first light emission period starts later than the start of the outputting of the selection signal by a first time, and ends earlier than the time after one vertical scanning period of the start of outputting of the selection signal by a second time,
wherein the second light emission period starts later than the start of the outputting of the selection signal by the first time, and ends earlier than the time after one vertical scanning period of the start of outputting of the selection signal by the second time, and
wherein the first time and the second time are times shorter than one horizontal scanning period.

6. The electro-optic device according to claim 1, further comprising a parallax barrier formed of a plurality of opening portions and a plurality of light shield portions corresponding, one-to-one, to the plurality of pixel circuits,
wherein the plurality of opening portions leads light emitted from the first light emitting device, to a first area, and leads light emitted from the second light emitting device, to a second area.

7. The electro-optic device according to claim 1, further comprising lenticular lenses provided with a plurality of lenses corresponding, one-to-one, to the plurality of pixel circuits,
wherein the plurality of lenses lead light emitted from the first light emitting device, to a first area, and lead light emitted from the second light emitting device, to a second area.

8. An electronic apparatus comprising the electro-optic device according to claim 1.
